(19) United States
(12) Patent Application Publication
(10) Pub. No.: US 2026/0101595 A1
(43) Pub. Date: Apr. 9, 2026

(54) VISIBLE AND SHORT-WAVE INFRARED HYBRID SENSORS

(71) Applicant: SEMICONDUCTOR COMPONENTS INDUSTRIES, LLC, Scottsdale, AZ (US)

(72) Inventor: Swarnal BORTHAKUR, Boise, ID (US)

(73) Assignee: SEMICONDUCTOR COMPONENTS INDUSTRIES, LLC, Scottsdale, AZ (US)

(21) Appl. No.: 18/908,279

(22) Filed: Oct. 7, 2024

(51) Int. Cl. H01L 27/146; G01J 1/44

(52) U.S. Cl. CPC H10F 39/8023; G01J 1/44; H10F 39/011; H10F 39/8053; H10F 39/806; H10F 39/8063; H10F 39/807

(57) ABSTRACT

Visible and short-wave infrared (SWIR) hybrid sensors and methods for constructing such sensors. The method includes forming a first deep trench isolation (DTI), a second DTI, and a third DTI in a silicon substrate. A portion of the silicon substrate positioned between the second and third DTIs forms a silicon photodetector for detecting visible light. The method also includes etching a trench in the silicon substrate between the second and third DTIs. The trench is etched such that another portion of the silicon substrate remains between the second and thirds DTIs. The method further includes forming a SWIR photodetector within the trench for detecting SWIR light. The method also includes removing another portion of the silicon substrate such that the first, second, and third DTIs are exposed on a side of the silicon substrate. The method further includes forming a high-K dielectric layer on the silicon substrate.

### BACKGROUND

Image sensors are used in electronic devices such as cellular telephones, cameras, and computers to capture images. In particular, an electronic device is provided with an array of image sensor pixels arranged in a grid pattern. Each image sensor pixel receives incident photons, such as light, and converts the photons into electrical signals. Column circuitry is coupled to each column for reading out sensor signals from each image sensor pixel.

Time-of-Flight (ToF) sensing is used in many industrial applications such as logistics, factory automation, medical, health, and agriculture. ToF sensing is also used in many consumer applications such as augmented reality, virtual reality, gaming, and object scanning. ToF sensing is further used in many automotive applications such as in-cabin monitoring and Light Detection and Ranging (LIDAR). Indirect TOF (iToF) is one form of ToF sensing in which distance is measured by collecting reflected infrared light, such as short-wave infrared (SWIR) light, and discerning the phase shift between emitted and reflected infrared light.

### SUMMARY

It is desirable to integrate visible and SWIR light sensing into a single sensor. Silicon photodetector may be used to detect visible light and other types of photodetectors (such as germanium photodetectors) may be used to detect SWIR light. However, due to the lattice mismatch between silicon and germanium, growing germanium on silicon results in dark currents that degrade sensor performance. Thus, the present disclosure provides visible and SWIR hybrid sensors and methods for constructing such sensors that, among other things, prevent dark currents generated by SWIR photodetectors from flowing into silicon photodetectors.

The present disclosure provides a method for constructing a visible and short-wave infrared (SWIR) sensor. The method includes forming at least a first deep trench isolation (DTI), a second DTI, and a third DTI on a first side of a silicon substrate. A first portion of the silicon substrate positioned between the second DTI and the third DTI forms a silicon photodetector configured to detect visible light. The method also includes etching a trench on the first side of the silicon substrate between the second DTI and the third DTI. The trench is etched such that a second portion of the silicon substrate remains between the second DTI and the third DTI. The method further includes forming a SWIR photodetector within the trench. The SWIR photodetector is configured to detect SWIR light. The method also includes removing a third portion of the silicon substrate such that the first DTI, the second DTI, and the third DTI are exposed on a second side of the silicon substrate opposite the first side. The method further includes forming a high-K dielectric layer on the second side of the silicon substrate.

The present disclosure also provides another method for constructing a visible and SWIR sensor. The method includes etching a trench on a first side of a silicon substrate. The method also includes forming a SWIR photodetector within the trench. The SWIR photodetector is configured to detect SWIR light. The method further includes forming a first DTI on the first side of the silicon substrate. The method also includes forming a second DTI on the first side of the silicon substrate and adjacent to a first side of the SWIR photodetector. A first portion of the silicon substrate positioned between the first DTI and the second DTI forms a silicon photodetector configured to detect visible light. The method further includes forming a third DTI on the first side of the silicon substrate and adjacent to a second side of the SWIR photodetector opposite the first side of the SWIR photodetector. The method also includes removing a second portion of the silicon substrate such that the first DTI, the second DTI, and the third DTI are exposed on a second side of the silicon substrate opposite the first side of the silicon substrate. The method further includes forming a high-K dielectric layer on the second side of the silicon substrate.

The present disclosure further provides an image sensor for visible and SWIR sensing. The image sensor includes, in one implementation, a first DTI, a second DTI, a third DTI, a silicon photodetector, a SWIR photodetector a high-K dielectric layer. The first DTI, the second DTI, and the third DTI are formed in a silicon substrate. The first DTI, the second DTI, and the third DTI are positioned substantially parallel to each other. The silicon photodetector is configured to detect visible light. The silicon photodetector is positioned between the first DTI and the second DTI. The SWIR photodetector is configured to detect SWIR light. The SWIR photodetector is positioned between the second DTI and the third DTI. The high-K dielectric layer is positioned over at least the first DTI, the second DTI, the third DTI, the silicon photodetector, and the SWIR photodetector. A portion of the silicon substrate is positioned between the SWIR photodetector and the high-K dielectric layer.

### BRIEF DESCRIPTION OF THE DRAWINGS

For a detailed description of example implementations, reference will now be made to the accompanying drawings in which:

FIG. 1 is a block diagram of an example of an imaging system in accordance with some implementations;

FIG. 2 is a diagram of an example of an imaging system incorporated in a vehicle in accordance with some implementations;

FIG. 3 is a partial schematic and a partial block diagram of an example of an image sensor in accordance with some implementations;

FIG. 4 is a schematic of an example of circuitry in a pixel in accordance with some implementations;

FIG. 5 is a view of an example of a color pattern of pixels in accordance with some implementations;

FIGS. 6A through 6E are cross-sectional views during different steps of an example of a method for constructing the color pattern FIG. 5 in accordance with a first implementation;

FIG. 7 is a cross-sectional view of an example of the color pattern of FIG. 5 with spectral routers in accordance with some implementations;

FIG. 8 is a cross-sectional view of an example of the color pattern of FIG. 5 with spectral routers and pyramid trenches in accordance with some implementations;

FIG. 9 is a cross-sectional view of an example of the color pattern of FIG. 5 with spectral routers, spectral filters, and microlenses in accordance with some implementations;

FIG. 10 is a cross-sectional view of an example of the color pattern of FIG. 5 with spectral filters and microlenses in accordance with some implementations;

FIG. 11 is a flow diagram of an example of a method for constructing a visible and SWIR sensor in accordance with the first implementation shown in FIGS. 6A through 6E;

FIGS. 12A through 12E are cross-sectional views during different steps of an example of a method for constructing the color pattern FIG. 5 in accordance with a second implementation; and

FIG. 13 is a flow diagram of an example of a method for constructing a visible and SWIR sensor in accordance with the second implementation shown in FIGS. 12A through 12E.

### DEFINITIONS

Various terms are used to refer to particular system components. Different companies may refer to a component by different names – this document does not intend to distinguish between components that differ in name but not function. In the following discussion and in the claims, the terms “including” and “comprising” are used in an open-ended fashion, and thus should be interpreted to mean “including, but not limited to… .” Also, the term “couple” or “couples” is intended to mean either an indirect or direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

Terms defining an elevation, such as “above,” “below,” “upper”, and “lower” shall be locational terms in reference to a direction of light incident upon a pixel array and/or an image pixel. Light entering shall be considered to interact with or pass objects and/or structures that are “above” and “upper” before interacting with or passing objects and/or structures that are “below” or “lower.” Thus, the locational terms may not have any relationship to the direction of the force of gravity.

“About” in reference to a recited parameter shall mean the recited parameter plus or minus ten percent (+/- 10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

In relation to electrical devices, whether stand alone or as part of an integrated circuit, the terms “input” and “output” refer to electrical connections to the electrical devices, and shall not be read as verbs requiring action. For example, a differential amplifier, such as an operational amplifier, may have a first differential input and a second differential input, and these “inputs” define electrical connections to the operational amplifier, and shall not be read to require inputting signals to the operational amplifier.

“Controller” shall mean, alone or in combination, individual circuit components, an application specific integrated circuit (ASIC), a microcontroller with controlling software, a reduced-instruction-set computer (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

“Visible light” shall mean light with wavelengths ranging from about 400 and 750 nanometers (nm). “Short wave infrared light” or “SWIR light” shall mean light with wavelengths ranging from about 1,000 and 1,700 nm.

### DETAILED DESCRIPTION

The following discussion is directed to various implementations of the invention. Although one or more of these implementations may be preferred, the implementations disclosed should not be interpreted, or otherwise used, as limiting the scope of the present disclosure, including the claims. In addition, one skilled in the art will understand that the following description has broad application, and the discussion of any implementation is meant only to be exemplary of that implementation, and not intended to intimate that the scope of the present disclosure, including the claims, is limited to that implementation.

Various examples are directed to visible and short-wave infrared (SWIR) hybrid sensors and methods for constructing such hybrid sensors. More particularly, at least some examples are directed to sensors with silicon photodetectors for detecting visible light and germanium photodetectors for detecting SWIR light. More particularly, various examples are directed to pixels with spectral routers that steer visible and SWIR light according to wavelength. More particularly, various examples are directed to pixels with spectral filters that filter visible light according to wavelength. The specification now turns to an example system to orient the reader.

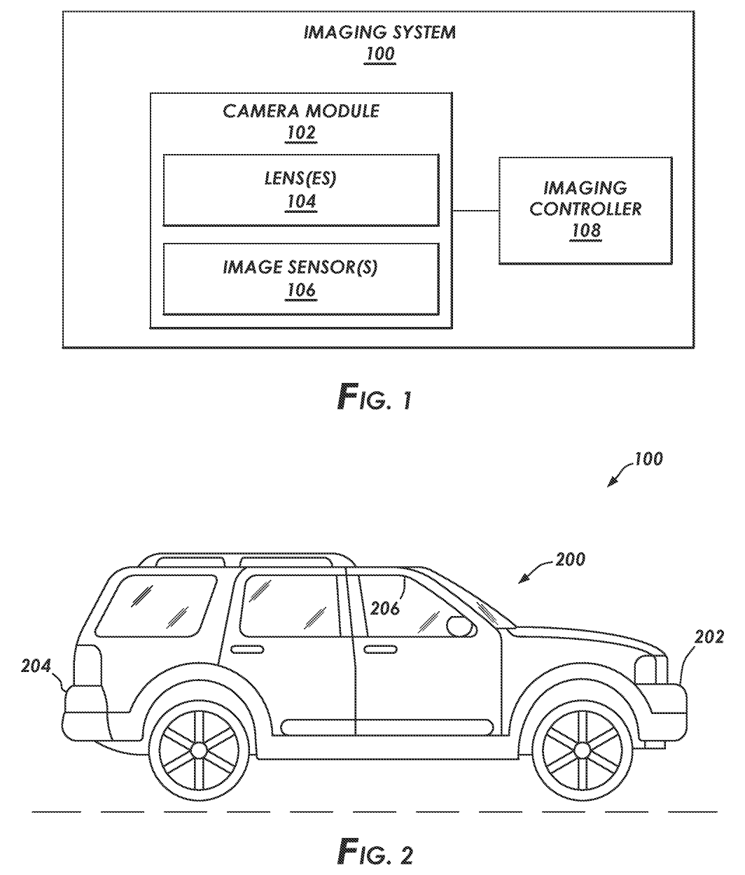

FIG. 1 shows an example of an imaging system 100. In particular, the imaging system 100 may be a portable electronic device such as a camera, a cellular telephone, a tablet computer, a webcam, a video camera, a video surveillance system, or a video gaming system with imaging capabilities. In other cases, the imaging system 100 may be an automotive imaging system. The imaging system 100 illustrated in FIG. 1 includes a camera module 102 that may be used to convert incoming light into digital image data. The camera module 102 may include one or more lenses 104 and one or more corresponding image sensors 106. The lenses 104 may include fixed and/or adjustable lenses. During image capture operations, light from a scene may be focused onto the image sensor 106 by the lenses 104. The image sensor 106 may comprise circuitry for converting analog pixel data into corresponding digital image data to be provided to the imaging controller 108. If desired, the camera module 102 may be provided with an array of lenses 104 and an array of corresponding image sensors 106.

The imaging controller 108 may include one or more integrated circuits. The imaging circuits may include image processing circuits, microprocessors, and storage devices, such as random-access memory, and non-volatile memory. The imaging controller 108 may be implemented using components that are separate from the camera module 102 and/or that form part of the camera module 102, for example, circuits that form part of the image sensor 106. Digital image data captured by the camera module 102 may be processed and stored using the imaging controller 108. Processed image data may, if desired, be provided to external equipment, such as computer, external display, or other device, using wired and/or wireless communications paths coupled to the imaging controller 108. The imaging controller 108 may perform Light Detection and Ranging (LIDAR) operations. For example, the digital image data captured by the camera module 102 may include one or more histograms, and the imaging controller 108 may perform an analysis of the one or more histograms to determine the combined time-of-flight of the outgoing interrogating infrared light and returning reflected infrared light.

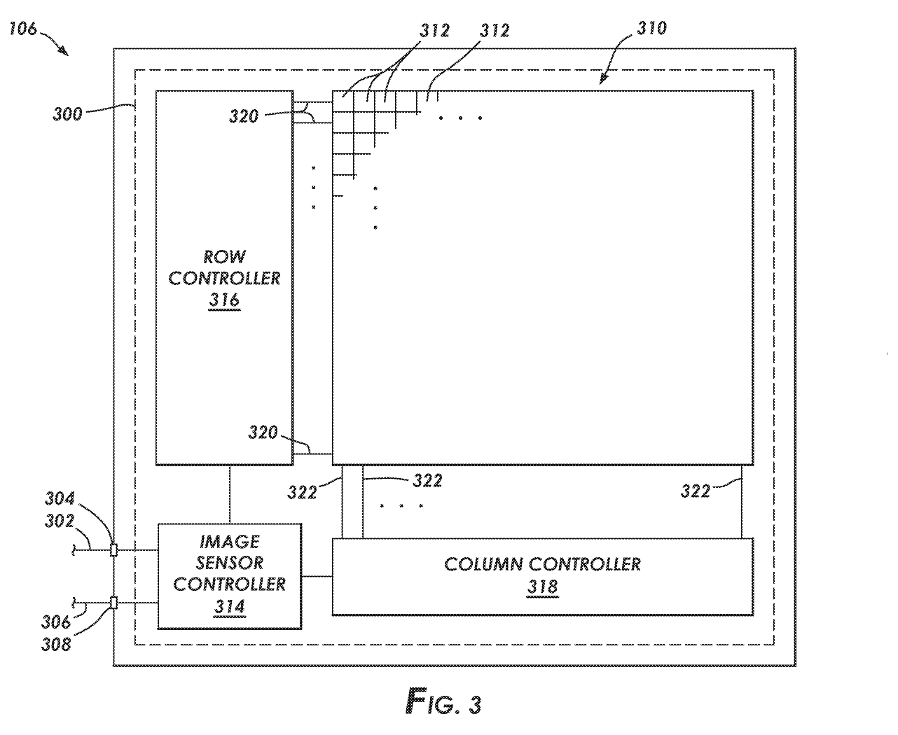

FIG. 2 shows another example of the imaging system 100. The imaging system 100 shown in FIG. 2 comprises an automobile or vehicle 200. The vehicle 200 is illustratively shown as a passenger vehicle, but the imaging system 100 may be other types of vehicles, including commercial vehicles, on-road vehicles, and off-road vehicles. Commercial vehicles may include busses and tractor-trailer vehicles. Off-road vehicles may include tractors and crop harvesting equipment. In the example of FIG. 2, the vehicle 200 includes a forward-looking camera module 202 arranged to capture images of scenes in front of the vehicle 200. The forward-looking camera module 202 can be used for any suitable purpose, such as lane-keeping assist, collision warning systems, distance-pacing cruise-control systems, autonomous driving systems, and proximity detection. The vehicle 200 further comprises a backward-looking camera module 204 arranged to capture images of scenes behind the vehicle 200. The backward-looking camera module 204 can be used for any suitable purpose, such as collision warning systems, reverse direction video, autonomous driving systems, proximity detection, monitoring position of overtaking vehicles, and backing up. The vehicle 200 further comprises a side-looking camera module 206 arranged to capture images of scenes beside the vehicle 200. The side-looking camera module 206 can be used for any suitable purpose, such as blind-spot monitoring, collision warning systems, autonomous driving systems, monitoring position of overtaking vehicles, lane-change detection, and proximity detection. In situations in which the imaging system 100 is a vehicle, the imaging controller 108 may be a controller of the vehicle 200. The discussion now turns in greater detail to the image sensor 106.

FIG. 3 shows an example of the image sensor 106. In particular, FIG. 3 shows that the image sensor 106 may comprise a substrate 300 of semiconductor material, such as silicon, encapsulated within packaging to create a packaged semiconductor device or packaged semiconductor product. Bond pads or other connection points of the substrate 300 couple to terminals of the image sensor 106. The connections may comprise a serial communication channel 302 coupled to a first terminal 304, and a capture input 306 coupled to a second terminal 308. Additional terminals will be present, such as ground, common, or power, but the additional terminals are omitted so as not to unduly complicate the figure. While a single instance of the substrate 300 is shown, in other implementations, multiple substrates may be combined to form the image sensor 106 in a multi-chip module created before or after singulation.

The image sensor 106 shown in FIG. 3 includes a pixel array 310 with a plurality of pixels, such as pixels 312. The pixel array 310 may include, for example, hundreds or thousands of rows and columns of pixels 312. Control and readout of the pixel array 310 may be implemented by an image sensor controller 314 coupled to a row controller 316 and a column controller 318. The row controller 316 may receive row addresses from the image sensor controller 314 and supply corresponding row control signals to pixels 312, such as reset, row select, charge transfer, and readout control signals. The row control signals may be communicated over one or more conductors, such as row control paths 320.

The column controller 318 may be coupled to the pixel array 310 by way of one or more conductors, such as column lines 322. Column controllers may sometimes be referred to as column control circuits, readout circuits, or column decoders. The column lines 322 may be used for reading out pixel signals from pixels 312 and for supplying bias currents and/or bias voltages to pixels 312. If desired, during readout operations, a pixel row in the pixel array 310 may be selected using the row controller 316 and pixels signals generated by the pixels 312 in that pixel row can be read out along the column lines 322. The column controller 318 may include sample-and-hold circuitry for sampling and temporarily storing signals read out from the pixel array 310, amplifier circuitry, analog-to-digital conversion (ADC) circuitry, bias circuitry, column memory, latch circuitry for selectively enabling or disabling the column circuitry, or other circuitry that is coupled to one or more columns of pixels 312 in the pixel array 310 for operating the pixels 312 and for reading out pixel signals from the pixel array 310. ADC circuitry in the column controller 318 may convert analog pixel values received from the pixel array 310 into corresponding digital data. The column controller 318 may supply the digital data to the image sensor controller 314 and/or the imaging controller 108 of FIG. 1 over, for example, the serial communication channel 302.

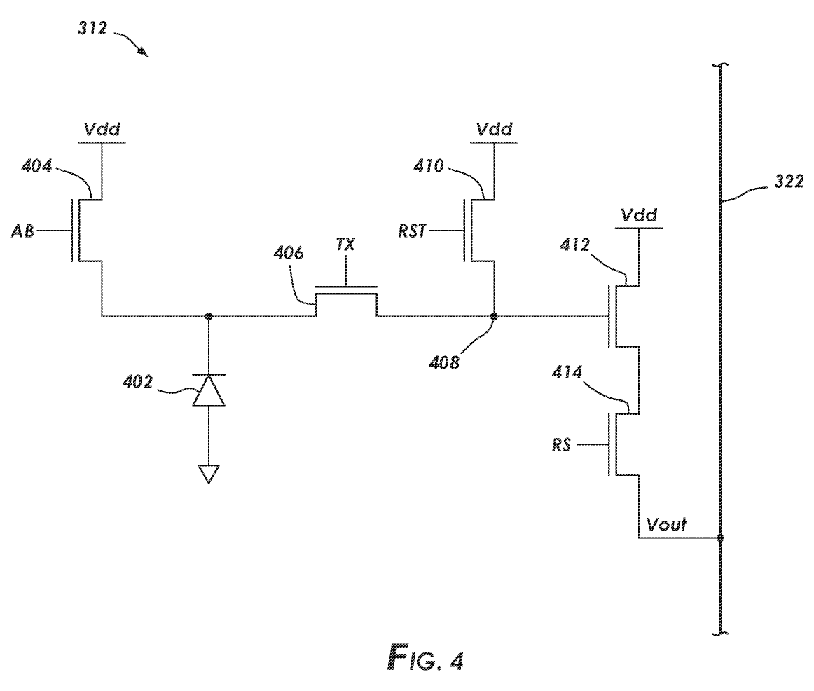

The pixels 312 in the pixel array 310 may include one or more photodiodes, one or more single-photon avalanche detectors (SPADs), one or more silicon photomultipliers (SiPMs), or a combination thereof. FIG. 4 is an electrical schematic of an example of one of the pixels 312 in the pixel array 310. In particular, the pixel 312 shown in FIG. 4 includes a photodetector 402 in the example form of a photodiode, an anti-blooming transistor 404, a transfer transistor 406, a floating diffusion 408, a reset transistor 410, a source-follower transistor 412, and a row select transistor 414. The photodetector 402 defines an anode coupled to ground or common, and a cathode coupled to the anti-blooming transistor 404 and the transfer transistor 406. The anti-blooming transistor 404 selectively connects the photodetector 402 to a positive pixel power supply voltage, such as supply voltage Vdd. The transfer transistor 406 selectively connects the photodetector 402 to the floating diffusion 408. The reset transistor 410 selectively connects the floating diffusion 408 to the positive pixel power supply voltage. The source-follower transistor 412 buffers a signal associated with charge stored in the floating diffusion 408. The row select transistor 414 selectively connects the source-follower transistor 412 to one of the column lines 322. In some implementations, some or all of the pixels 312 in the pixel array 310 may have the same components in the same configuration as the pixel 312 shown in FIG. 4. In other implementations, some or all of the pixels 312 in the pixel array 310 may have fewer components, additional components, or different components in different configurations than the pixel 312 shown in FIG. 4.

Before an image is acquired, the pixel array 310 is reset. For example, an anti-blooming control signal AB may be asserted to reset the pixel array 310. As shown in FIG. 4, the anti-blooming control signal AB is applied to the gate terminal of the anti-blooming transistor 404. Thus, the anti-blooming transistor 404 is made conductive when the anti-blooming control signal AB is asserted. Making the anti-blooming transistor 404 conductive resets the photodetector 402 to a voltage equal or close to the supply voltage Vdd. Further, to reset the pixel array 310, a reset control signal RST may be asserted. As shown in FIG. 4, the reset control signal RST is applied to the gate terminal of the reset transistor 410. Thus, the reset transistor 410 is made conductive when the reset control signal RST is asserted. Making the reset transistor 410 conductive resets the floating diffusion 408 to a voltage equal or close to the supply voltage Vdd. After the floating diffusion 408 is reset, the reset control signal RST may be de-asserted to turn off the reset transistor 410.

After the pixel array 310 is reset, the photodetector 402 gathers incoming light during an integration time. The photodetector 402 converts the light to electrical charge. To arrange the pixel array 310 to be sensitive to light during the integration time, the anti-blooming control signal AB may be de-asserted to turn off the anti-blooming transistor 404. After (or during) the integration time, a transfer control signal TX may be asserted. As shown in FIG. 4, the transfer control signal TX is applied to the gate terminal of the transfer transistor 406. Thus, the transfer transistor 406 is made conductive when the transfer control signal TX is asserted. Making the transfer transistor 406 conductive transfers charge generated by the photodetector 402 to the floating diffusion 408. After the charge is transferred to the floating diffusion 408, the transfer control signal TX may be de-asserted to turn off the transfer transistor 406. Next, a row select control signal RS may be asserted. As shown in FIG. 4, the row select control signal RS is applied to the gate terminal of the row select transistor 414. Thus, the row select transistor 414 is made conductive when the row select control signal RS is asserted. Making the row select transistor 414 conductive outputs an output signal Vout that is representative of the magnitude of charge stored in the floating diffusion 408. The output signal Vout is one example of a “pixel signal.” When the row select control signal RS is asserted, one of the column lines 322 can be used to route the output signal Vout to readout circuitry, such as the column controller 318 in FIG. 3. After the output signal Vout is output, the row select control signal RS may be de-asserted to turn off the row select transistor 414.

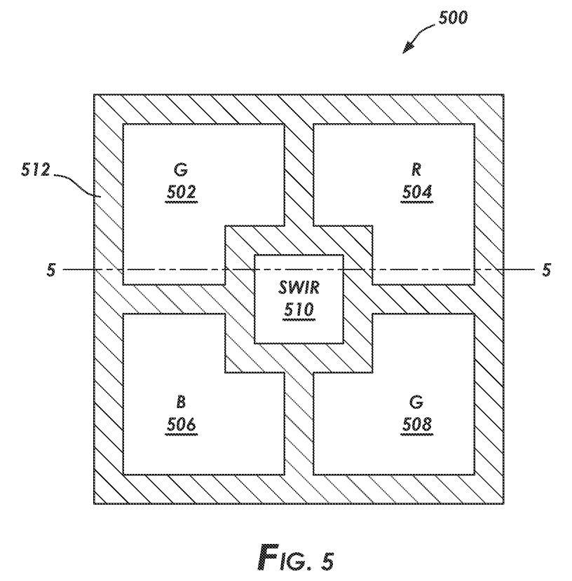

FIG. 5 shows a view of an example of a color pattern 500 of pixels. In particular, the color pattern 500 shown in FIG. 5 includes a first green pixel 502, a red pixel 504, a blue pixel 506, a second green pixel 508, and a SWIR pixel 510. As shown in FIG. 5, a deep trench isolation (DTI) 512 resides between the first green pixel 502, the red pixel 504, the blue pixel 506, the second green pixel 508, and the SWIR pixel 510. The DTI 512 may comprise silicon dioxide, polysilicon, metals such as tungsten, or a combination thereof. In some implementations, each of the first green pixel 502, the red pixel 504, the blue pixel 506, and the second green pixel 508 have a two micrometer pitch.

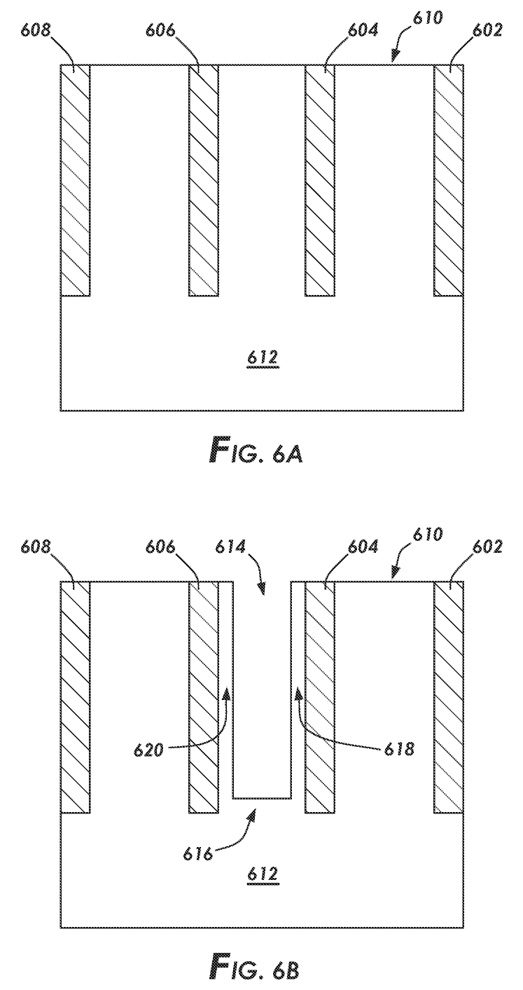

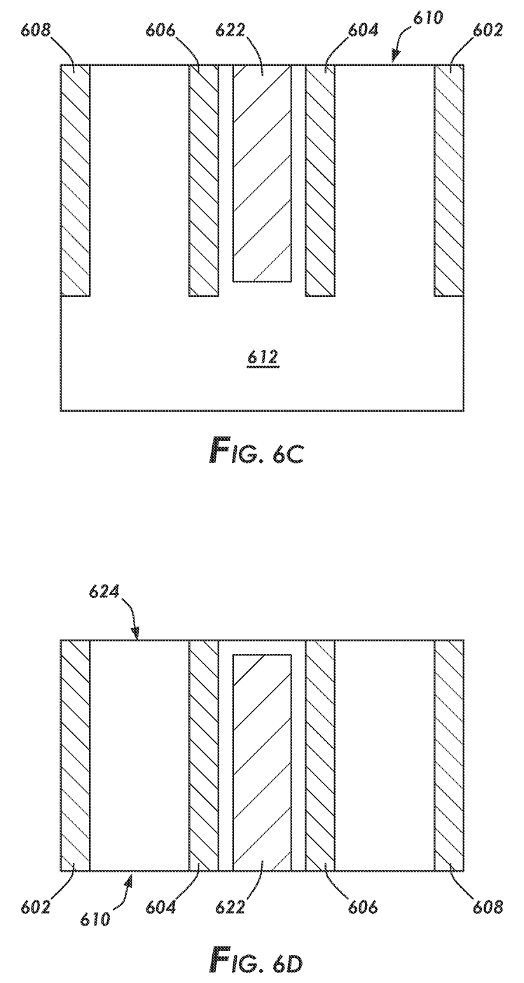

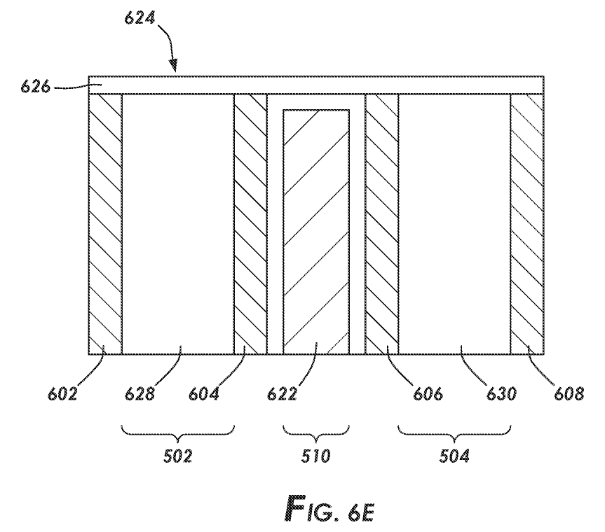

FIGS. 6A through 6E are cross-sectional views during different steps of an example of a method for constructing the color pattern 500 of FIG. 5 in accordance with a first implementation. The cross-sectional views in FIGS. 6A through 6E are taken at line 5-5 of FIG. 5.

In FIG. 6A, a first DTI 602, a second DTI 604, a third DTI 606, and a fourth DTI 608 are formed on a first side 610 of a silicon substrate 612. The first DTI 602, the second DTI 604, the third DTI 606, and the fourth DTI 608 are positioned substantially parallel to each other.

In FIG. 6B, a trench 614 is etched on the first side 610 of the silicon substrate 612. As shown in FIG. 6B, the trench 614 is etched such that a portion 616 of the silicon substrate 612 remains between the second DTI 604 and the third DTI 606. The portion 616 of the silicon substrate 612 between the second DTI 604 and the third DTI 606 is one example of a “first portion.” Germanium (and other SWIR-detecting material) cannot be grown directly on the second DTI 604. However, germanium can be grown on silicon. Thus, the trench 614 in FIG. 6B is etched such that a portion 618 of the silicon substrate 612 remains between the trench 614 and the second DTI 604. The portion 618 of the silicon substrate 612 between the trench 614 and the second DTI 604 is one example of a “second portion” and a “fourth portion.” Further, germanium cannot be grown directly on the third DTI 606. Thus, the trench 614 in FIG. 6B is etched such that a portion 620 of the silicon substrate 612 remains between the trench 614 and the third DTI 606. The portion 620 of the silicon substrate 612 between the trench 614 and the third DTI 606 is one example of a “third portion” and a “fifth portion.”

In FIG. 6C, a SWIR photodetector 622 is formed (for example, grown) within the trench 614. The SWIR photodetector 622 may comprise germanium, indium, gallium, arsenide, phosphorus, antimony, or any combination thereof. For example, the SWIR photodetector 622 may comprise germanium, indium gallium arsenide (InGaAs), indium arsenide (InAs), gallium arsenide (GaAs), indium antimony (InSb), or indium phosphorus (InP). In some implementations, the SWIR photodetector 622 may comprise multiple layers of different compounds. For example, the SWIR photodetector 622 may be created by first forming a layer of InGaAs on the silicon substrate 612 in the trench 614 and then forming a layer of GaAs on the layer of InGaAs. The SWIR photodetector 622 may comprise other combinations of different compounds such as InGaAs and gallium phosphorus (GaP), InSb and gallium antimony (GaSb), or InP and GaAs.

In FIG. 6D, a portion of the silicon substrate 612 is removed such that the first DTI 602, the second DTI 604, the third DTI 606, and the fourth DTI 608 are exposed on a second side 624 of the silicon substrate 612. Note that the views in FIGS. 6D through 6E are flipped vertically with respect to the views in FIGS. 6A through 6C. The removed portion of the silicon substrate 612 is one example of a “second portion” and a “third portion.” As shown in FIG. 6D, the second side 624 of the silicon substrate 612 is opposite the first side 610 of the silicon substrate 612.

In FIG. 6E, a high-K dielectric layer 626 is formed on the second side 624 of the silicon substrate 612. The high-K dielectric layer 626 comprises a high-K dielectric such as aluminum oxide, hafnium oxide, tantalum pentoxide, or a combination thereof.

The portion of the silicon substrate 612 between the first DTI 602 and the second DTI 604 in FIG. 6E forms a first silicon photodetector 628 configured to detect green light. The first silicon photodetector 628 may be part of the first green pixel 502 in the color pattern 500 of FIG. 5. Further, the portion of the silicon substrate 612 between the third DTI 606 and the fourth DTI 608 in FIG. 6E forms a second silicon photodetector 630 configured to detect red light. The second silicon photodetector 630 may be part of the red pixel 504 in the color pattern 500 of FIG. 5. The SWIR photodetector 622 in FIG. 6E is configured to detect SWIR light. The SWIR photodetector 622 may be part of the SWIR pixel 510 in the color pattern 500 of FIG. 5.

As shown in FIG. 6E, the SWIR photodetector 622, the first silicon photodetector 628, and the second silicon photodetector 630 are positioned on a plane that is substantially parallel to the high-K dielectric layer 626. In other words, the SWIR photodetector 622 is not positioned above or below the first silicon photodetector 628 or the second silicon photodetector 630. Positioning a SWIR photodetector below a silicon photodetector may reduce the detection capability of the SWIR photodetector. Further, stacking the photodetectors increases the overall size of the pixel array. Positioning the SWIR photodetector 622 on the same plane as the first silicon photodetector 628 or the second silicon photodetector 630, as shown in FIG. 6E, increases the detection capability of the SWIR photodetector 622 and reduces the overall size of the pixel array 310. Further, as shown in FIG. 6E, there is a gap between the SWIR photodetector 622 and the high-K dielectric layer 626. Due to this gap, any dark current generated by the SWIR photodetector 622 is prevented from flowing into the first silicon photodetector 628 or the second silicon photodetector 630.

In some implementations, additional steps may be performed while constructing the color pattern 500 of FIG. 5. For example, after the SWIR photodetector 622 is formed in FIG. 6C, a stack of sensor and application specific integrated circuit (ASIC) layers may be formed the first side 610 of the silicon substrate 612. These sensor and ASIC layers may include interlayer dielectrics (ILDs) that connect to the SWIR photodetector 622, the first silicon photodetector 628, the second silicon photodetector 630, or a combination thereof.

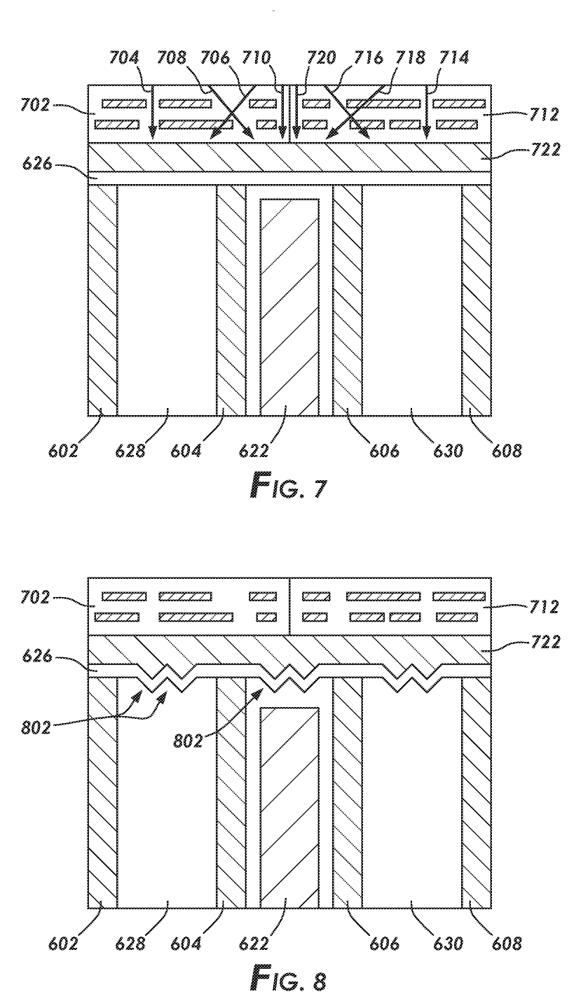

In some implementations, incident light entering the pixel array 310 is routed to the photosensitive regions via spectral routers. A spectral router (or nanophotonic light guide) is an optical structure that accepts photons incident on an upper surface. The spectral router then diverts photons from the upper surface to the underlying photosensitive regions of photodiodes. For example, FIG. 7 shows that a green spectral router 702 is positioned above the first silicon photodetector 628 and above a portion of the SWIR photodetector 622. The green spectral router 702 is configured to direct incident light in the green wavelength range to the first silicon photodetector 628, such as wavelengths between about 500 and 590 nanometers (nm). For example, the portion of the green spectral router 702 positioned above the first silicon photodetector 628 is configured to pass incident light in the green wavelength range to the first silicon photodetector 628. Consider, for purposes of discussion, green light entering the green spectral router 702 above the first silicon photodetector 628. An example of such green light is shown in FIG. 7 by arrow 704. The green light initially encounters a portion of the green spectral router 702 positioned above the first silicon photodetector 628, which passes the green light to the first silicon photodetector 628. Further, the portion of the green spectral router 702 positioned above the SWIR photodetector 622 is configured to direct incident light in the green wavelength range to the first silicon photodetector 628. Consider, for purposes of discussion, green light entering the green spectral router 702 above the SWIR photodetector 622. An example of such green light is shown in FIG. 7 by arrow 706. The green light initially encounters a portion of the green spectral router 702 positioned above the SWIR photodetector 622, which directs the green light to the first silicon photodetector 628.

The green spectral router 702 is also configured to direct SWIR light to the SWIR photodetector 622. For example, the portion of the green spectral router 702 positioned above the first silicon photodetector 628 is configured to direct SWIR light to the SWIR photodetector 622. Consider, for purposes of discussion, SWIR light entering the green spectral router 702 above the first silicon photodetector 628. An example of such SWIR light is shown in FIG. 7 by arrow 708. The SWIR light initially encounters a portion of the green spectral router 702 positioned above the first silicon photodetector 628, which directs the SWIR light to the SWIR photodetector 622. Further, the portion of the green spectral router 702 positioned above the SWIR photodetector 622 is configured to pass SWIR light to the SWIR photodetector 622. Consider, for purposes of discussion, SWIR light entering the green spectral router 702 above the SWIR photodetector 622. An example of such SWIR light is shown in FIG. 7 by arrow 710. The SWIR light initially encounters a portion of the green spectral router 702 positioned above the SWIR photodetector 622, which passes the infrared light to the SWIR photodetector 622.

FIG. 7 also shows that a red spectral router 712 is positioned above the second silicon photodetector 630 and above a portion of the SWIR photodetector 622. The red spectral router 712 is configured to direct incident light in the red wavelength range to the second silicon photodetector 630, such as wavelengths between about 590 and 690 nm. For example, the portion of the red spectral router 712 positioned above the second silicon photodetector 630 is configured to pass incident light in the red wavelength range to the second silicon photodetector 630. Consider, for purposes of discussion, red light entering the red spectral router 712 above the second silicon photodetector 630. An example of such red light is shown in FIG. 7 by arrow 714. The red light initially encounters a portion of the red spectral router 712 positioned above the second silicon photodetector 630, which passes the red light to the second silicon photodetector 630. Further, the portion of the red spectral router 712 positioned above the SWIR photodetector 622 is configured to direct incident light in the red wavelength range to the second silicon photodetector 630. Consider, for purposes of discussion, red light entering the red spectral router 712 above the SWIR photodetector 622. An example of such red light is shown in FIG. 7 by arrow 716. The red light initially encounters a portion of the red spectral router 712 positioned above the SWIR photodetector 622, which directs the red light to the second silicon photodetector 630.

The red spectral router 712 is also configured to direct SWIR light to the SWIR photodetector 622. For example, the portion of the red spectral router 712 positioned above the second silicon photodetector 630 is configured to direct SWIR light to the SWIR photodetector 622. Consider, for purposes of discussion, SWIR light entering the red spectral router 712 above the second silicon photodetector 630. An example of such SWIR light is shown in FIG. 7 by arrow 718. The SWIR light initially encounters a portion of the red spectral router 712 positioned above the second silicon photodetector 630, which directs the SWIR light to the SWIR photodetector 622. Further, the portion of the red spectral router 712 positioned above the SWIR photodetector 622 is configured to pass SWIR light to the SWIR photodetector 622. Consider, for purposes of discussion, SWIR light entering the red spectral router 712 above the SWIR photodetector 622. An example of such SWIR light is shown in FIG. 7 by arrow 720. The SWIR light initially encounters a portion of the red spectral router 712 positioned above the SWIR photodetector 622, which passes the SWIR light to the SWIR photodetector 622.

In some implementations, a dielectric layer 722 is formed between the high-K dielectric layer 626 and the green spectral router 702 and between the high-K dielectric layer 626 and the red spectral router 712. The dielectric layer 722 may comprise an oxide (such as silicon diode) or a nitride (such as silicon nitride).

In some implementations, the high-K dielectric layer 626 and the dielectric layer 722 are formed to include light scattering structures that disperse SWIR light evenly across the photosensitive regions. For example, in FIG. 8, the high-K dielectric layer 626 and the dielectric layer 722 include a plurality of pyramids 802 configured to disperse SWIR light evenly across the SWIR photodetector 622, the first silicon photodetector 628, and the second silicon photodetector 630. The plurality of pyramids 802 are one example of a light scattering structure. In some implementations, the high-K dielectric layer 626 and the dielectric layer 722 may include other light scattering structures, such as vertical trenches.

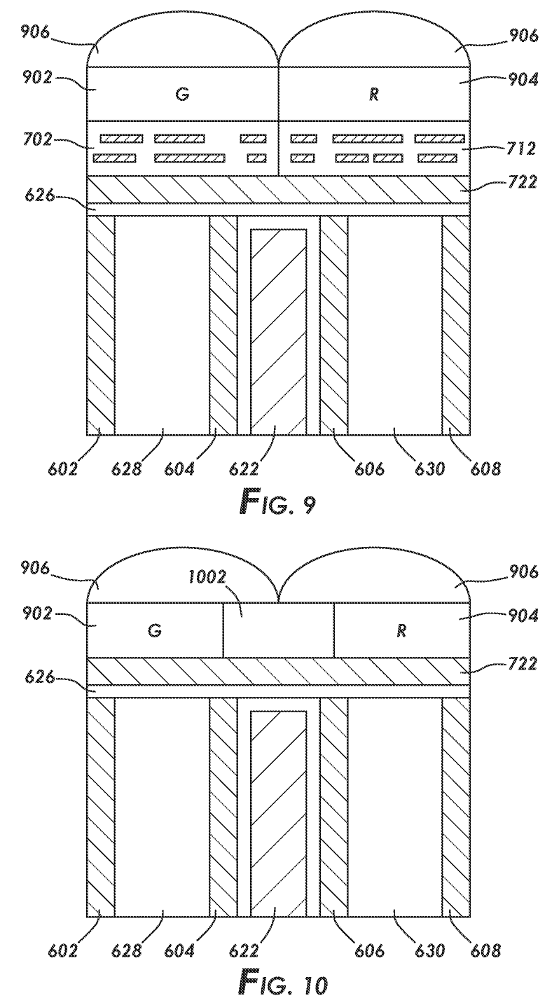

In some implementations, spectral filters are positioned above the spectral routers to filter visible light. For example, FIG. 9 shows that a green spectral filter 902 is positioned above the green spectral router 702. The green spectral filter 902 is configured to pass visible light in the green wavelength range and block (or absorb) visible light outside of the green wavelength range. The green spectral filter 902 is also configured to pass SWIR light. The green spectral filter 902 is one example of a “first spectral filter.” FIG. 9 further shows that a red spectral filter 904 is positioned above the red spectral router 712. The red spectral filter 904 is configured to pass visible light in the red wavelength range and block (or absorb) visible light outside of the red wavelength range. The red spectral filter 904 is also configured to pass SWIR light. The red spectral filter 904 is one example of a “second spectral filter.” FIG. 9 also shows that a plurality of microlenses 906 are positioned over the green spectral filter 902 and the red spectral filter 904, as shown in FIG. 9. The plurality of microlenses 906 collimate light entering the pixel array 310.

In some implementations, instead of spectral routers, only spectral filters are used to control incident light entering the pixel array 310. For example, in FIG. 10, the green spectral filter 902 and the red spectral filter 904 are not positioned above the SWIR photodetector 622. Rather, FIG. 10 shows that a SWIR spectral filter 1002 is positioned over the SWIR photodetector 622. The SWIR spectral filter 1002 is configured to pass SWIR light and block (or absorb) visible light. The SWIR spectral filter 1002 is one example of a “second spectral filter.” In some implementations, the plurality of microlenses 906 are positioned over the green spectral filter 902, the red spectral filter 904, and the SWIR spectral filter 1002, as shown in FIG. 10. Although only two microlenses are shown in FIG. 10, more than two microlenses may be placed over a two-by-two cell.

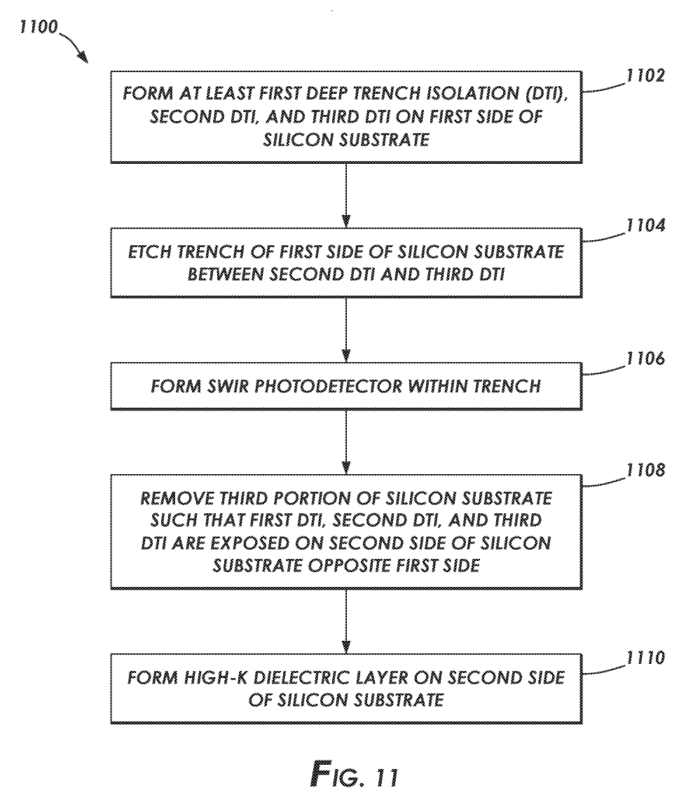

FIG. 11 is a flow diagram of an example of a method 1100 for constructing a visible and SWIR sensor in accordance with the first implementation described above in relation to FIGS. 6A through 6E. For simplicity of explanation, the method 1100 is depicted in FIG. 11 and described as a series of operations. However, the operations can occur in various orders and/or concurrently, and/or with other operations not presented and described herein. At block 1102, at least a first deep trench isolation (DTI), a second DTI, and a third DTI are formed on a first side of a silicon substrate. For example, the first DTI 602, the second DTI 604, and the third DTI 606 may be formed on the first side 610 of the silicon substrate 612, as shown in FIG. 6A. At block 1104, a trench is etched on the first side of the silicon substrate between the second DTI and the third DTI. For example, the trench 614 may be etched on the first side 610 of the silicon substrate 612 between the second DTI 604 and the third DTI 606, as shown in FIG. 6B. At block 1106, a SWIR photodetector is formed within the trench. For example, the SWIR photodetector 622 may be formed within the trench 614, as shown in FIG. 6C. At block 1108, a third portion of the silicon substrate is removed such that the first DTI, the second DTI, and the third DTI are exposed on a second side of the silicon substrate opposite the first side. For example, a portion of the silicon substrate 612 may be removed such that the first DTI 602, the second DTI 604, and the third DTI 606 are exposed on the second side 624 of the silicon substrate 612 opposite the first side 610, as shown in FIG. 6D. At block 1110, a high-K dielectric layer is formed on the second side of the silicon substrate. For example, the high-K dielectric layer 626 may be formed on the second side 624 of the silicon substrate 612, as shown in FIG. 6E.

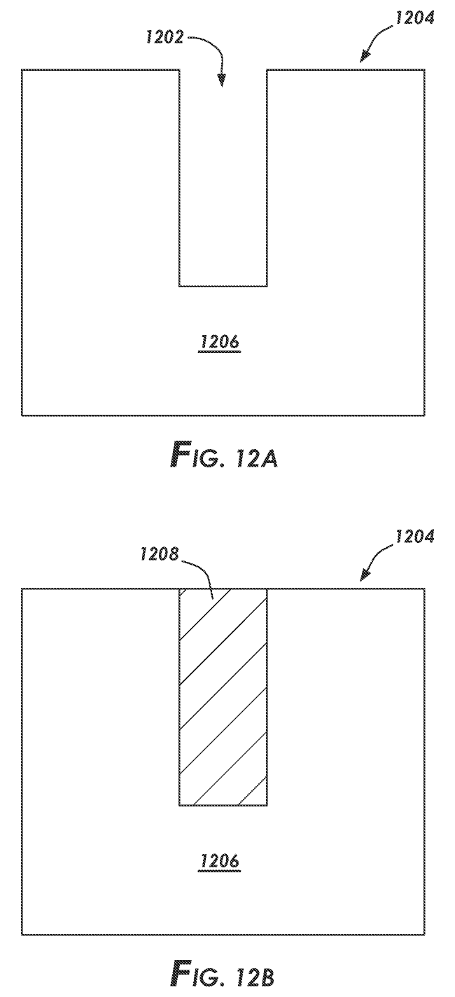

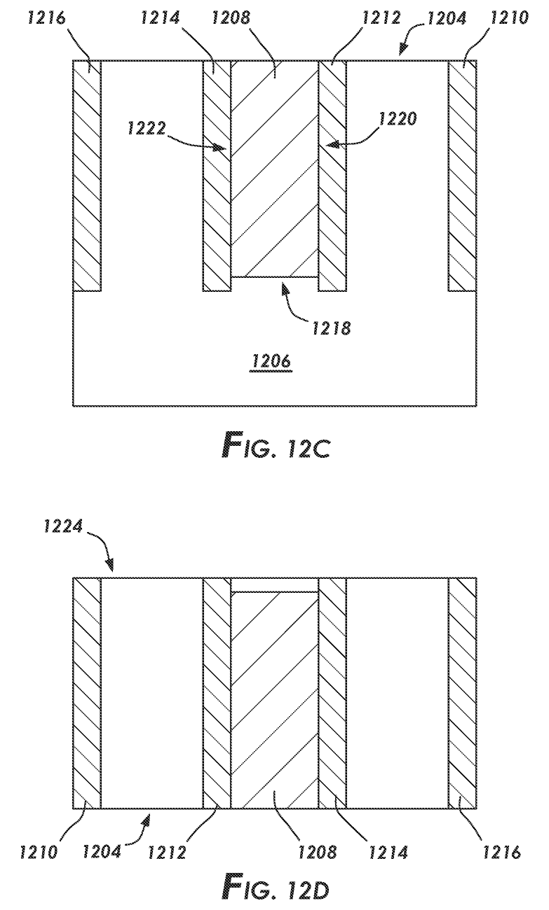

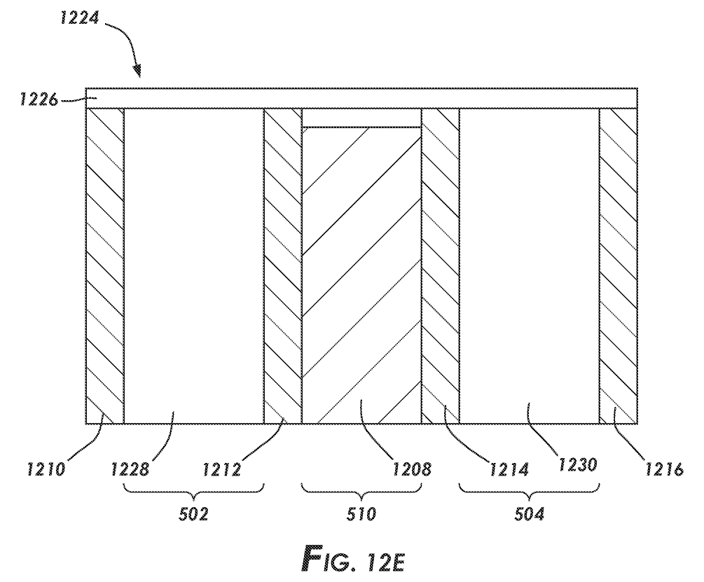

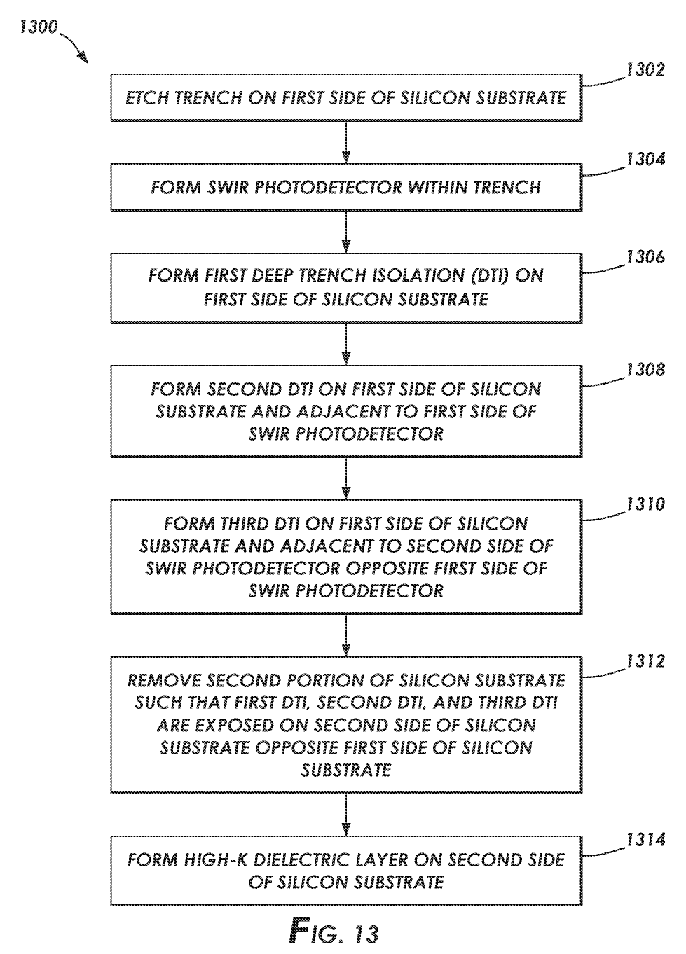

FIGS. 12A through 12E are cross-sectional views during different steps of an example of a method for constructing the color pattern 500 of FIG. 5 in accordance with a second implementation. The cross-sectional views in FIGS. 12A through 12E are taken at line 5-5 of FIG. 5. In FIG. 12A, a trench 1202 is etched on a first side 1204 of a silicon substrate 1206. In FIG. 12B, a SWIR photodetector 1208 is formed (for example, grown) within the trench 1202. The SWIR photodetector 1208 may comprise any of the compounds or any of the combination of compounds described above in relation to the SWIR photodetector 622 shown in FIGS. 6C through 6E.

In FIG. 12C, a first DTI 1210, a second DTI 1212, a third DTI 1214, and a fourth DTI 1216 are formed on the first side 1204 of the silicon substrate 1206. The first DTI 1210, the second DTI 1212, the third DTI 1214, and the fourth DTI 1216 are positioned substantially parallel to each other. As shown in FIG. 12C, the second DTI 1212 and the third DTI 1214 are formed such that a portion 1218 of the silicon substrate 1206 remains between the second DTI 1212 and the third DTI 1214. The second DTI 1212 in FIG. 12C is positioned adjacent to a first side 1220 of the SWIR photodetector 1208. The third DTI 1214 in FIG. 12C is positioned adjacent to a second side 1222 of the SWIR photodetector 1208. The second side 1222 of the SWIR photodetector 1208 is positioned opposite the first side 1220 of the SWIR photodetector 1208. Forming the SWIR photodetector 1208 within the trench 1202 may cause damage to the portions of the silicon substrate 1206 positioned around the trench 1202. Thus, the second DTI 1212 and the third DTI 1214 are positioned adjacent to opposite sides of the SWIR photodetector 1208 so that any damaged portions of the silicon substrate 1206 are removed and replaced by the second DTI 1212 or the third DTI 1214.

In FIG. 12D, a portion of the silicon substrate 1206 is removed such that the first DTI 1210, the second DTI 1212, the third DTI 1214, and the fourth DTI 1216 are exposed on a second side 1224 of the silicon substrate 1206. Note that the views in FIGS. 12D through 12E are flipped vertically with respect to the views in FIGS. 12A through 12C. As shown in FIG. 12D, the second side 1224 of the silicon substrate 1206 is opposite the first side 1204 of the silicon substrate 1206. In FIG. 12E, a high-K dielectric layer 1226 is formed on the second side 1224 of the silicon substrate 1206.

The portion of the silicon substrate 1206 between the first DTI 1210 and the second DTI 1212 in FIG. 12E forms a first silicon photodetector 1228 configured to detect green light. The first silicon photodetector 1228 may be part of the first green pixel 502 in the color pattern 500 of FIG. 5. Further, the portion of the silicon substrate 1206 between the third DTI 1214 and the fourth DTI 1216 in FIG. 12E forms a second silicon photodetector 1230 configured to detect red light. The second silicon photodetector 1230 may be part of the red pixel 504 in the color pattern 500 of FIG. 5. The SWIR photodetector 1208 in FIG. 12E is configured to detect SWIR light. The SWIR photodetector 1208 may be part of the SWIR pixel 510 in the color pattern 500 of FIG. 5. As shown in FIG. 12E, the SWIR photodetector 1208, the first silicon photodetector 1228, and the second silicon photodetector 1230 are positioned on a plane that is substantially parallel to the high-K dielectric layer 1226. Positioning the SWIR photodetector 1208 on the same plane as the first silicon photodetector 1228 or the second silicon photodetector 1230, as shown in FIG. 12E, increases the detection capability of the SWIR photodetector 1208 and reduces the overall size of the pixel array 310 then if the SWIR photodetector 1208 was positioned below the first silicon photodetector 1228 or the second silicon photodetector 1230. Further, as shown in FIG. 12E, there is a gap between the SWIR photodetector 1208 and the high-K dielectric layer 1226. Due to this gap, any dark current generated by the SWIR photodetector 1208 is prevented from flowing into the first silicon photodetector 1228 or the second silicon photodetector 1230.

FIG. 13 is a flow diagram of an example of a method 1300 for constructing a visible and SWIR sensor in accordance with the second implementation described above in relation to FIGS. 12A through 12E. For simplicity of explanation, the method 1300 is depicted in FIG. 13 and described as a series of operations. However, the operations can occur in various orders and/or concurrently, and/or with other operations not presented and described herein. At block 1302, a trench is etched on a first side of a silicon substrate. For example, the trench 1202 may be etched on the first side 1204 of the silicon substrate 1206, as shown in FIG. 12A. At block 1304, a SWIR photodetector is formed within the trench. For example, the SWIR photodetector 1208 is formed within the trench 1202, as shown in FIG. 12B. At block 1306, a first DTI is formed on the first side of the silicon substrate. For example, the first DTI 1210 may be formed on the first side 1204 of the silicon substrate 1206, as shown in FIG. 12C. At block 1308, a second DTI is formed on the first side of the silicon substrate and adjacent to a first side of the SWIR photodetector. For example, the second DTI 1212 is formed on the first side 1204 of the silicon substrate 1206 and adjacent to the first side 1220 of the SWIR photodetector 1208, as shown in FIG. 12C. At block 1310, a third DTI is formed on the first side of the silicon substrate and adjacent to a second side of the SWIR photodetector opposite the first side of the SWIR photodetector. For example, the third DTI 1214 is formed on the first side 1204 of the silicon substrate 1206 and adjacent to the second side 1222 of the SWIR photodetector 1208 which is opposite the first side 1220 of the SWIR photodetector 1208, as shown in FIG. 12C. At block 1312, a third portion of the silicon substrate is removed such that the first DTI, the second DTI, and the third DTI are exposed on a second side of the silicon substrate opposite the first side of the silicon substrate. For example, a portion of the silicon substrate 1206 may be removed such that the first DTI 1210, the second DTI 1212, and the third DTI 1214 are exposed on the second side 1224 of the silicon substrate 1206 which is opposite the first side 1204 of the silicon substrate 1206, as shown in FIG. 12D. At block 1314, a high-K dielectric layer is formed on the second side of the silicon substrate. For example, the high-K dielectric layer 1226 may be formed on the second side 1224 of the silicon substrate 1206, as shown in FIG. 12E.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s).

The above discussion is meant to be illustrative of the principles and various implementations of the present invention. Numerous variations and modifications will become apparent to those skilled in the art once the above disclosure is fully appreciated. It is intended that the following claims be interpreted to embrace all such variations and modifications.

What is claimed is:

1. A method for constructing a visible and short-wave infrared (SWIR) sensor, the method comprising:
forming at least a first deep trench isolation (DTI), a second DTI, and a third DTI on a first side of a silicon substrate, wherein a first portion of the silicon substrate positioned between the second DTI and the third DTI forms a silicon photodetector configured to detect visible light;
etching a trench on the first side of the silicon substrate between the second DTI and the third DTI, wherein the trench is etched such that a second portion of the silicon substrate remains between the second DTI and the third DTI;
forming a SWIR photodetector within the trench, wherein the SWIR photodetector is configured to detect SWIR light;
removing a third portion of the silicon substrate such that the first DTI, the second DTI, and the third DTI are exposed on a second side of the silicon substrate opposite the first side; and
forming a high-K dielectric layer on the second side of the silicon substrate.

2. The method of claim 1, wherein the trench is further etched such that:
a fourth portion of the silicon substrate remains between the trench and the first DTI, and
a fifth portion of the silicon substrate remains between the trench and the second DTI.

3. The method of claim 1, further comprising forming a spectral router above the high-K dielectric layer, wherein the spectral router is configured to:
route visible light within a color wavelength range to the silicon photodetector, and
route the SWIR light to the SWIR photodetector.

4. The method of claim 3, wherein the high-K dielectric layer is further formed to include one or more light scattering structures.

5. The method of claim 3, further comprising:
forming a spectral filter on the spectral router, wherein the spectral filter is configured to block visible light outside of the color wavelength range; and
forming a microlens on the spectral filter.

6. The method of claim 1, further comprising:
forming a first spectral filter over the first portion of the silicon substrate, wherein the first spectral filter is configured to block visible light outside of a color wavelength range;
forming a second spectral filter over the SWIR photodetector, wherein the second spectral filter is configured to block the visible light; and
forming a microlens over the first spectral filter and at least a portion of the second spectral filter.

7. A method for constructing a visible and short-wave infrared (SWIR) sensor, the method comprising:
etching a trench on a first side of a silicon substrate;
forming a SWIR photodetector within the trench, wherein the SWIR photodetector is configured to detect SWIR light;
forming a first deep trench isolation (DTI) on the first side of the silicon substrate;
forming a second DTI on the first side of the silicon substrate and adjacent to a first side of the SWIR photodetector, wherein a first portion of the silicon substrate positioned between the first DTI and the second DTI forms a silicon photodetector configured to detect visible light;
forming a third DTI on the first side of the silicon substrate and adjacent to a second side of the SWIR photodetector opposite the first side of the SWIR photodetector;
removing a second portion of the silicon substrate such that the first DTI, the second DTI, and the third DTI are exposed on a second side of the silicon substrate opposite the first side of the silicon substrate; and
forming a high-K dielectric layer on the second side of the silicon substrate.

8. The method of claim 7, further comprising forming a spectral router above the high-K dielectric layer, wherein the spectral router is configured to:
route visible light within a color wavelength range to the silicon photodetector, and
route the SWIR light to the SWIR photodetector.

9. The method of claim 8, further comprising forming a dielectric layer between the high-K dielectric layer and the spectral router.

10. The method of claim 8, further comprising:
forming a spectral filter on the spectral router, wherein the spectral filter is configured to block visible light outside of the color wavelength range; and
forming a microlens on the spectral filter.

11. The method of claim 7, further comprising:
forming a first spectral filter over the silicon photodetector, wherein the first spectral filter is configured to block visible light outside of a color wavelength range;
forming a second spectral filter over the SWIR photodetector, wherein the second spectral filter is configured to block the visible light; and
forming a microlens over the first spectral filter and at least a portion of the second spectral filter.

12. An image sensor for visible and short-wave infrared (SWIR) sensing, comprising:
a pixel array including:
at least a first deep trench isolation (DTI), a second DTI, and a third DTI formed in a silicon substrate and positioned substantially parallel to each other,
a silicon photodetector configured to detect visible light and positioned between the first DTI and the second DTI,
a SWIR photodetector configured to detect SWIR light and positioned between the second DTI and the third DTI,
a high-K dielectric layer positioned over at least the first DTI, the second DTI, the third DTI, the silicon photodetector, and the SWIR photodetector, and
a portion of the silicon substrate positioned between the SWIR photodetector and the high-K dielectric layer.

13. The image sensor of claim 12, wherein the portion of the silicon substrate positioned between the SWIR photodetector and the high-K dielectric layer is a first portion of the silicon substrate, wherein the pixel array further includes:
a second portion of the silicon substrate positioned between the SWIR photodetector and the second DTI, and
a third portion of the silicon substrate positioned between the SWIR photodetector and the third DTI.

14. The image sensor of claim 12, wherein the silicon photodetector and the SWIR photodetector are positioned on a plane substantially parallel to the high-K dielectric layer.

15. The image sensor of claim 12, wherein the pixel array further includes a spectral router positioned over the silicon photodetector and at least a portion of the SWIR photodetector, and wherein the spectral router is configured to:
route visible light within a color wavelength range to the silicon photodetector, and
route the SWIR light to the SWIR photodetector.

16. The image sensor of claim 15, wherein the high-K dielectric layer including one or more light scattering structures.

17. The image sensor of claim 15, wherein the pixel array further includes:
a spectral filter positioned over the spectral router and configured to block visible light outside of the color wavelength range, and
a microlens positioned over the spectral filter.

18. The image sensor of claim 12, wherein the pixel array further includes:
a first spectral filter positioned over the silicon photodetector and configured to block visible light outside of a color wavelength range,
a second spectral filter positioned over the SWIR photodetector and configured to block the visible light, and
a microlens positioned over the first spectral filter and at least a portion of the second spectral filter.

19. An imaging system, comprising:
a lens system;
the image sensor of claim 12; and
an imaging controller,
wherein the image sensor is in operational relationship with the lens system and is electronically coupled to the imaging controller.

20. The imaging system of claim 19, wherein the imaging system is at least one selected from the group consisting of an automobile, a vehicle, a camera, a cellular telephone, a tablet computing, a webcam, a video camera, a video surveillance system, and a video gaming system.
